(19) United States
(12) Patent Application Publication
(10) Pub. No.: US 2009/0279256 A1
(43) Pub. Date: Nov. 12, 2009

(54) Heat-dissipating structure

(76) Inventors: Chang-Hung Peng, Chung-Ho City (TW); Chung-Chin Huang, Chung-Ho City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/385,227

(22) Filed: Apr. 2, 2009

(30) Foreign Application Priority Data
May 12, 2008 (TW) 97208177

(51) Int. Cl. H05K 7/20

(52) U.S. Cl. 361/697; 361/704

(57) ABSTRACT

A heat-dissipating structure includes a base seat, a plurality of heat-dissipating fins and a heat pipe. The heat-dissipating fins are separated from each other by a predetermined distance, and each heat-dissipating fin has a base portion and at least one bending portion that is bent and extended upwards from one side of the base portion. The length of each bending portion is the same to or larger than the length of the base portion. The heat pipe is connected with the base seat, and at least one side of the heat pipe passing through the base portions of the heat-dissipating fins. Therefore, the present invention can obtain a perfect heat-dissipating coefficient and a better heat-dissipating efficiency by using the bending portion that is bent and extended upwards from one side of the base portion.

### BACKGROUND OF THE INVENTION

1. Field of the Invention

The present invention relates to a heat-dissipating structure, in particular, to a heat-dissipating structure having a plurality of heat-dissipating fins and each heat-dissipating fin having at least one long bending portion disposed on its one side in order to obtain a perfect heat-dissipating coefficient.

2. Description of Related Art

As the computer industry has developed the processing velocity of electronic devices has become faster and faster, subsequently the heat generated by the CPU has also increased. In order to dissipate the heat from the heat source to the external environment, a heat sink and a fan are usually used to help dissipate the heat. For example, when a computer is on work, the electronic components of the computer would generate heat and electromagnetic radiation. The heat generates from the electronic components would increase temperature and effect efficiency of the computer. Hence, the computer would crash easily due to high temperature of electronic components.

In the prior art, the heat sink includes a heat-conducting block, a plurality of fins that are horizontal to each other, and a heat pipe. The fins are plate structures horizontal to each other, and the heat pipe is connected between the heat-conducting block and the fins. When using the heat sink, the heat-conducting block is disposed on a heat-generating element in order to absorb the heat generated by the heat-generating element. The heat absorbed by the heat-conducting block is transmitted to the fins through the heat pipe in order to dissipate the heat efficiently.

However, when using the heat sink, the heat sink should generate thermal airstream that flows from top to bottom. Because the fins are horizontal to each other (it means the fins are vertical to the thermal airstream), both the heat-dissipating coefficient and the heat-dissipating efficiency are reduced.

### SUMMARY OF THE INVENTION

In view of the aforementioned issues, the present invention provides a heat-dissipating structure that has a plurality of heat-dissipating fins. Each heat-dissipating fin has at least one long bending portion disposed on its one side and extended upwards from its one side, so that heat is concentrated on the bending portion of each heat-dissipating fin in order to obtain a perfect heat-dissipating coefficient and a better heat-dissipating efficiency.

To achieve the above-mentioned objectives, the present invention provides a heat-dissipating structure, including: a base seat, a plurality of heat-dissipating fins and a heat pipe. The heat-dissipating fins are separated from each other by a predetermined distance, and each heat-dissipating fin has a base portion and at least one bending portion that is bent and extended upwards from one side of the base portion. The length of each bending portion is that same to or larger than the length of the base portion. The heat pipe is connected with the base seat, and at least one side of the heat pipe passing through the base portions of the heat-dissipating fins.

Therefore, each heat-dissipating fin has at least one long bending portion disposed on its one side, so that the present invention can obtain a perfect heat-dissipating coefficient, a good heat-conducting effect, and a better heat-dissipating efficiency.

In order to further understand the techniques, means and effects the present invention takes for achieving the prescribed objectives, the following detailed descriptions and appended drawings are hereby referred, such that, through which, the purposes, features and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIG. 1 is a perspective, assembled view of the heat-dissipating structure according to the first embodiment of the present invention;

FIG. 2 is a front view of the heat-dissipating structure according to the first embodiment of the present invention;

FIG. 3 is a perspective, assembled view of the heat-dissipating structure mating with a heat-dissipating fan according to the first embodiment of the present invention;

FIG. 4 is a front view of the heat-dissipating structure according to the second embodiment of the present invention;

FIG. 5 is a front view of the heat-dissipating structure according to the third embodiment of the present invention;

FIG. 6 is a perspective, assembled view of the heat-dissipating structure according to the fourth embodiment of the present invention;

FIG. 7 is a perspective, assembled view of the heat-dissipating structure according to the fifth embodiment of the present invention;

FIG. 8 is a perspective, assembled view of the heat-dissipating structure according to the sixth embodiment of the present invention;

FIG. 9 is a perspective, assembled view of the heat-dissipating structure according to the seventh embodiment of the present invention; and

FIG. 10 is a perspective, assembled view of the heat-dissipating structure according to the eighth embodiment of the present invention.

### DETAILED DESCRIPTION OF THE PREFERRED EMBODIMENTS

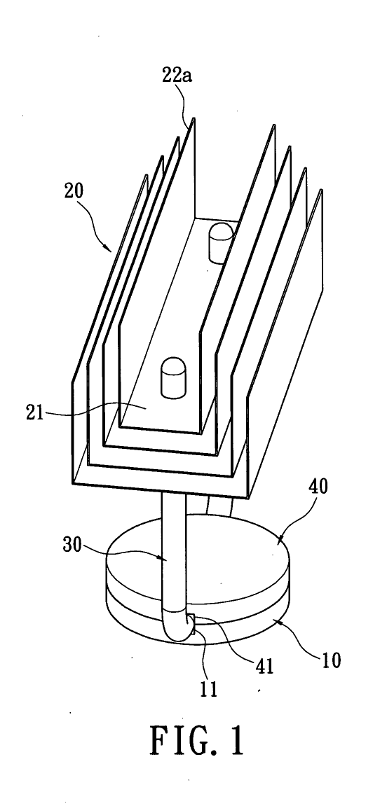

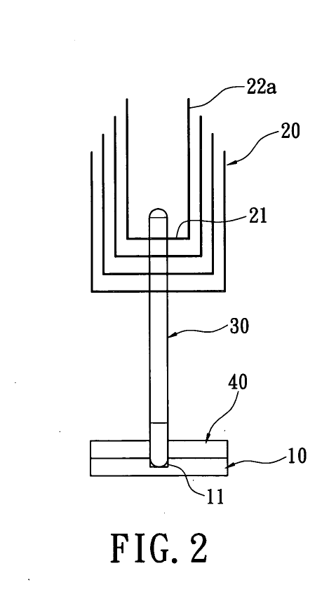

Referring to FIGS. 1 and 2, the first embodiment of the present invention provides a heat-dissipating structure, including: a base seat 10, a plurality of heat-dissipating fins 20, a heat pipe 30 and a cover 40. The base seat 10 is made of metal material with high thermal conductivity. The base seat 10 has a long groove 11 formed on its top surface, the bottom side of the heat pipe 30 is received in the long groove 11.

The heat-dissipating fins 20 are separated from each other by a predetermined distance. The height of each heat-dissipating fin 20 is different. Each heat-dissipating fin 20 has a base portion 21 and two bending portions 22a. Each bending portion 22a has a rectangular shape, and the length of each bending portion 22a is that same to or larger than the length of the base portion 21. The two bending portions 22a of each heat-dissipating fin 20 are vertically bent and extended upwards from two opposite sides of the base portion 21 of each heat-dissipating fin 20 respectively, so that the cross-section of each heat-dissipating fin 20 is shown as a U shape. However, the U shape does not limit the present invention. Of course, the bending portion 22a can be bent and extended upwards from only one side of the base portion 21. In the first embodiment, the positions of the ends of the bending portions 22a of the heat-dissipating fins 20 are decreased gradually from inner to outer.

The middle portion of the heat pipe 30 is assembled in the groove 11 of the base seat 10 in order to connect the heat pipe 30 with the base seat 10, so that heat can be transmitted from the base seat 10 to the heat pipe 30. In the first embodiment, the two sides of the heat pipe 30 pass through the base portions 21 of the heat-dissipating fins 20 at the same time, so that heat can be transmitted from the base seat 10 to the heat-dissipating fins 20 via the heat pipe 30. Of course, the present invention can use only one side of the heat pipe 30 to pass through the base portions 21 of the heat-dissipating fins 20.

The cover 40 is made of metal material. The cover 40 has a concave portion 41 formed on its bottom surface and corresponding to the heat pipe 30. The concave portion 41 abuts against the top side of the middle portion of the heat pipe 30. The cover 40 covers the heat pipe 30 in order to fix the heat pipe 30 on the base seat 10. The present invention is accomplished by assembling above-mentioned components.

The present invention is applied to dissipate heat from light-generating element that is assembled in the computer or LED lamp. The base seat 10 of the heat-dissipating structure can be attached to the surface of the heat-generating element in order to absorb heat of the heat-generating element, and the heat is transmitted to the heat-dissipating fins 20 to be dissipated via heat pipe 30.

When the heat is transmitted from the base seat 10 to the heat-dissipating fins 20, thermal airstream flows from top to bottom. The two bending portions 22a of each heat-dissipating fin 20 are vertically bent and extended upwards from two opposite sides of the base portion 21 of each heat-dissipating fin 20 respectively, and the length of each bending portion 22a is that same to or larger than the length of the base portion 21, so that the extending direction of the bending portions 22a is the same to the flow direction of the thermal airstream. Hence, the thermal airstream is dissipated easily by using the large area of the lateral surface of each bending portion 22a. In other words, the heat is transmitted and concentrated quickly from each base portion 21 to the two corresponding bending portion 22a, so that the thermal conductibility of the present invention is perfect. Even if the heat is dissipated by nature convection, the present invention still has a perfect thermal conductibility.

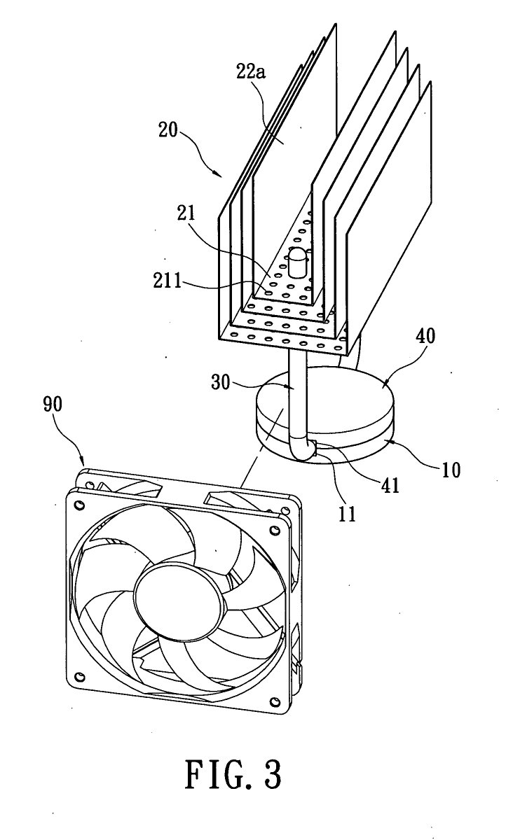

Furthermore, a heat-dissipating fan 90 can be disposed beside any side of the heat-dissipating fins 20 as shown in FIG. 3. In the present invention, the heat-dissipating fan 90 is an axial fan, but it does not limit the present invention. The heat-dissipating fan 90 can applied to blow the heat-dissipating structure in order to increase the heat-dissipating velocity. In addition, the assembly position of the heat-dissipating fan 90 does not limit in the present invention.

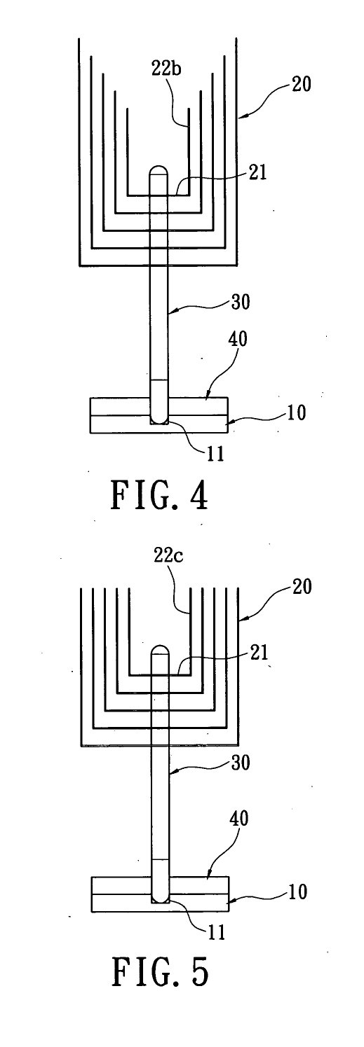

Referring to FIG. 4, the labels of the second embodiment is that same to the labels of the first embodiment. The difference between the second embodiment and the first embodiment is that: in the second embodiment, the positions of the ends of the bending portions 22b of the heat-dissipating fins 20 are increased gradually from inner to outer.

Referring to FIG. 5, the labels of the third embodiment is that same to the labels of the first embodiment. The difference between the third embodiment and the first embodiment is that: in the third embodiment, the positions of the ends of the bending portions 22c of the heat-dissipating fins 20 are the same.

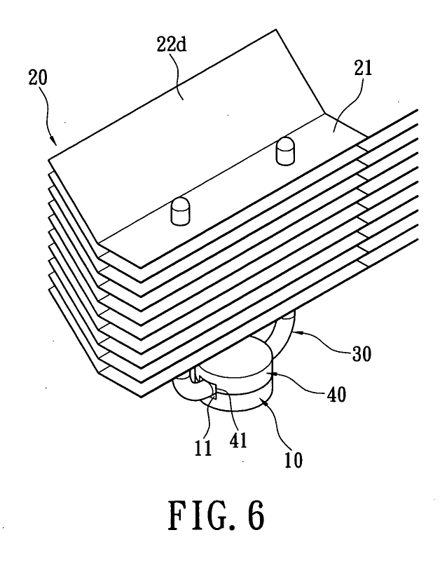

Referring to FIG. 6, the labels of the fourth embodiment is that same to the labels of the first embodiment. The difference between the fourth embodiment and the first embodiment is that: in the fourth embodiment, the two bending portions 22d of each heat-dissipating fin 20 are slantwise bent and extended upwards from two opposite sides of the base portion 21 of each heat-dissipating fin 20 respectively,

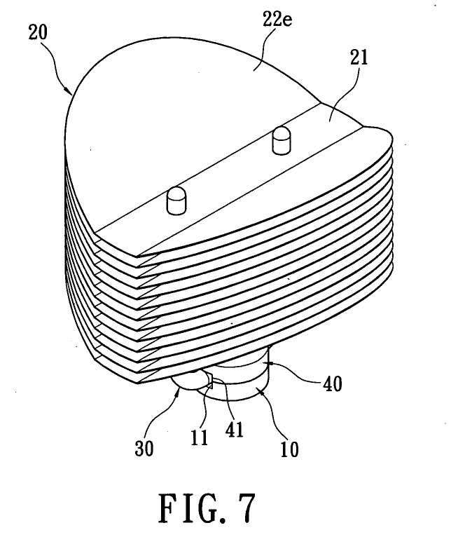

Referring to FIG. 7, the labels of the fifth embodiment is that same to the labels of the first embodiment. The difference between the fifth embodiment and the first embodiment is that: in the fifth embodiment, each bending portions 22e of each heat-dissipating fin 20 has a semicircle shape, and the two bending portions 22e of each heat-dissipating fin 20 are slantwise bent and extended upwards from two opposite sides of the base portion 21 of each heat-dissipating fin 20 respectively,

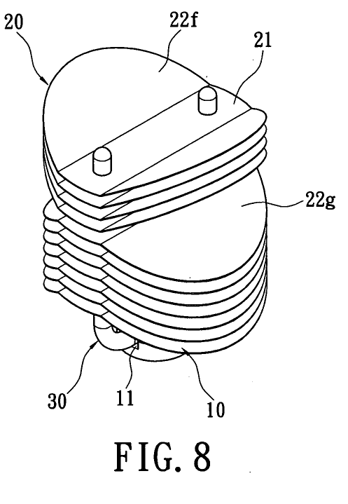

Referring to FIG. 8, the labels of the sixth embodiment is that same to the labels of the fifth embodiment. The difference between the sixth embodiment and the fifth embodiment is that: in the sixth embodiment, the two bending portions 22f of each upper heat-dissipating fin 20 are slantwise bent and extended upwards from two opposite sides of the base portion 21 of each upper heat-dissipating fin 20 respectively. The two bending portions 22g of each lower heat-dissipating fin 20 are slantwise bent and extended downwards from two opposite sides of the base portion 21 of each lower heat-dissipating fin 20 respectively.

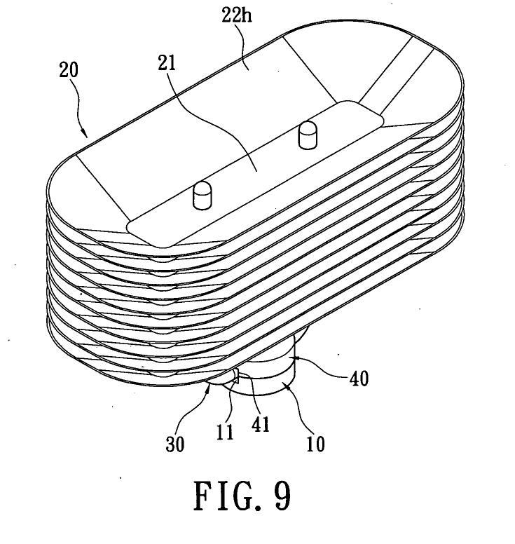

Referring to FIG. 9, the labels of the seventh embodiment is that same to the labels of the first embodiment. The difference between the seventh embodiment and the first embodiment is that: in the seventh embodiment, each heat-dissipating fin 20 has a bending portion 22h, and the bending portion 22h is slantwise bent and extended upwards from a periphery of the base portion 21. Hence, each heat-dissipating fin 20 is shown as a long disk shape.

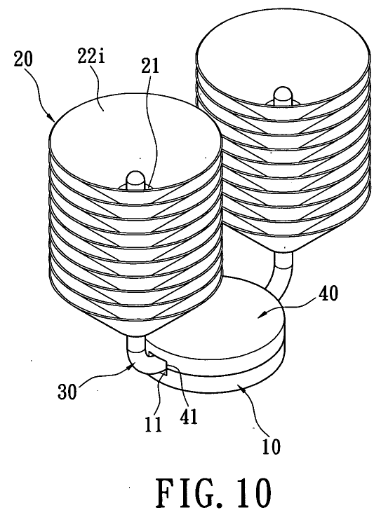

Referring to FIG. 10, the labels of the eighth embodiment is that same to the labels of the seventh embodiment. The difference between the eighth embodiment and the seventh embodiment is that: in the eighth embodiment, the two sides of the heat pipe 30 respectively pass through many different heat-dissipating fins 20. Each heat-dissipating fin 20 has a bending portion 22i, and the bending portion 22i is slantwise bent and extended upwards from a periphery of the base portion 21. Hence, each heat-dissipating fin 20 is shown as a bowl shape.

In above-mentioned embodiments, the base portion 21 of each heat-dissipating fin 20 has a plurality of heat-dissipating holes 211 passing therethrough as shown in FIG. 3, so that the thermal airstream can pass quickly through the heat-dissipating holes 211 as many fluid channels in order to increase the rise velocity of the thermal airstream. Hence, most of heat can be dissipated by using the heat-dissipating holes 211.

Hence, the heat is transmitted and concentrated quickly from each base portion to the two corresponding long bending portion. The extending direction of the bending portions is the same to the flow direction of the thermal airstream, so that the thermal conductibility of the present invention is perfect. In addition, the thermal airstream is dissipated easily by using the large area of the lateral surface of each bending portion, and even if the heat is dissipated by nature convection, the present invention still has a perfect thermal conductibility, so that the present invention can obtain a perfect heat-dissipating coefficient, a good heat-conducting effect, and a better heat-dissipating efficiency.

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. A heat-dissipating structure comprising:
a base seat;
a plurality of heat-dissipating fins separated from each other, and each heat-dissipating fin having a base portion and at least one bending portion that is bent and extended upwards from one side of the base portion, wherein the length of each bending portion is the same to or larger than the length of the base portion; and
a heat pipe connected with the base seat, and at least one side of the heat pipe passing through the base portions of the heat-dissipating fins.

2. The heat-dissipating structure according to claim 1, wherein the base seat has a groove, and the heat pipe is received in the groove.

3. The heat-dissipating structure according to claim 1, wherein the base portion of each heat-dissipating fin has a plurality of heat-dissipating holes passing therethrough.

4. The heat-dissipating structure according to claim 1, wherein the cross-section of each heat-dissipating fin has a U shape.

5. The heat-dissipating structure according to claim 1, wherein the positions of the ends of the bending portions of the heat-dissipating fins are decreased gradually from inner to outer.

6. The heat-dissipating structure according to claim 1, wherein the positions of the ends of the bending portions of the heat-dissipating fins are increased gradually from inner to outer.

7. The heat-dissipating structure according to claim 1, wherein the positions of the ends of the bending portions of the heat-dissipating fins are the same.

8. The heat-dissipating structure according to claim 1, wherein each heat-dissipating fin further includes an another bending portion, and the two bending portions of each heat-dissipating fin are vertically bent and extended upwards from two opposite sides of the base portion of each heat-dissipating fin respectively.

9. The heat-dissipating structure according to claim 1, wherein each heat-dissipating fin further includes an another bending portion, and the two bending portions of each heat-dissipating fin are slantwise bent and extended upwards from two opposite sides of the base portion of each heat-dissipating fin respectively.

10. The heat-dissipating structure according to claim 1, wherein the bending portion is slantwise bent and extended upwards from a periphery of the base portion, so that each heat-dissipating fin has a long disk shape.

11. The heat-dissipating structure according to claim 1, wherein the bending portion is slantwise bent and extended upwards from a periphery of the base portion, so that each heat-dissipating fin has a bowl shape.

12. The heat-dissipating structure according to claim 1, further comprising a heat-dissipating fan disposed beside one side of the heat-dissipating fins.

13. The heat-dissipating structure according to claim 1, further comprising a cover covering the heat pipe.
